(19) United States
(12) Patent Application Publication
(10) Pub. No.: US 2014/0111070 A1
(43) Pub. Date: Apr. 24, 2014

(54) UNIVERSALLY CONFIGURABLE RACK MOUNT SIDE PANELS

(71) Applicant: Jon Brian Ehlen, Milpitas, CA (US)

(72) Inventor: Jon Brian Ehlen, Milpitas, CA (US)

(21) Appl. No.: 13/657,602

(22) Filed: Oct. 22, 2012

(51) Int. Cl. H05K 7/14

(52) U.S. Cl. CPC H05K 7/14
USPC 312/223.2; 29/525.01; 29/426.1

(57) ABSTRACT

Side panels that are secured to the posts on opposing sides of a server rack include a plurality of slots that are used to support rack-mounted equipment. Sides of a chassis including computing device chassis include protruding pins that can be extended into the slots in the opposing panels. The protruding pins support the chassis on the side panels and secure the chassis inside the server rack. The side panels may also include holes to allow additional fasteners to secure the chassis to the server rack.

### BACKGROUND

This invention relates generally to rack-mounted computing equipment, and in particular to mechanisms for mounting computing devices to a rack.

Conventionally, computing devices such as servers and networking equipment are mounted to a server rack. A conventional server rack comprises two or four vertical posts with a series of threaded holes. To mount a component in the rack, a user must use screws and bolts to affix secure mounting brackets (e.g., rack mount ears) on the sides of the component to the holes in the vertical posts. To configure a component to slide in and out of the rack, additional hardware, such as sliding rails or a ball bearing system, must be mounted to the rack to allow sliding. Typically, installing and removing components in a traditional server rack is highly time-consuming, and for data centers with a large amount of rack-mounted equipment, the process can also be expensive because of time spent by technicians performing installation and removal.

In addition, existing rack-mounting standards place significant restrictions on the size of the equipment that can be mounted to a rack and the way in which equipment of different heights can be combined on a rack. For example, the EIA-310-D standard for 19-inch equipment cannot accommodate components with a width greater than 17.6 inches, and components can only be mounted at height intervals of one rack unit (1 U), which is defined in the DIA-310-D standard as 1.75 inches. Sliding rails and other sliding hardware must be installed within the width of 17.6 inches, further reducing the horizontal space for the component.

### SUMMARY

Embodiments of the invention provide configurable side panels that are secured to the posts on opposing sides of a server rack. Each side panel includes a plurality of slots for supporting rack-mounted equipment. Rather than directly securing a chassis to the vertical posts with screws and bolts, the sides of the chassis include protruding pins that can be extended into the slots in the opposing panels. Hence, the protruding pins support the chassis on the side panels and keep the chassis secure inside the server rack. The protruding pins occupy significantly less horizontal space within the server rack than conventional mounting systems, such as mounting brackets or sliding rails. In addition, the side panels may be mounted collinearly with the posts of the server rack, allowing a chassis to occupy the entire horizontal space between the posts. In some embodiments, the slots included on the side panels are spaced at intervals of one-half of a rack unit (0.5 U), allowing chasses with non-integer rack-unit heights (e.g., 0.5 U, 1.5 U, 2.5 U) to be mounted in the server rack with less wasted space. In some embodiments, the side panels also include a plurality of holes allowing a chassis to also be secured to the side panels with fasteners.

### BRIEF DESCRIPTION OF THE DRAWINGS

FIGS. 1A-1B illustrate a side panel installed in a server rack, according to one embodiment.

FIGS. 2A-2B illustrate examples of chasses suitable to be mounted on side panels.

FIGS. 3A-3D illustrate a process for mounting a chassis to side panels of a rack, according to one embodiment.

FIGS. 3E-3F illustrate a process for removing a chassis from side panels of a rack, according to one embodiment.

FIG. 4A is a side view of a side panel, according to one embodiment.

FIG. 4B is a front view of a server rack including a plurality of computing assets mounted on side panels, according to one embodiment.

FIG. 5 is a cross-sectional view of two side panels, according one embodiment.

The figures depict various embodiments of the present invention for purposes of illustration only. One skilled in the art will readily recognize from the following discussion that alternative embodiments of the structures and methods illustrated herein may be employed without departing from the principles of the invention described herein.

### DETAILED DESCRIPTION

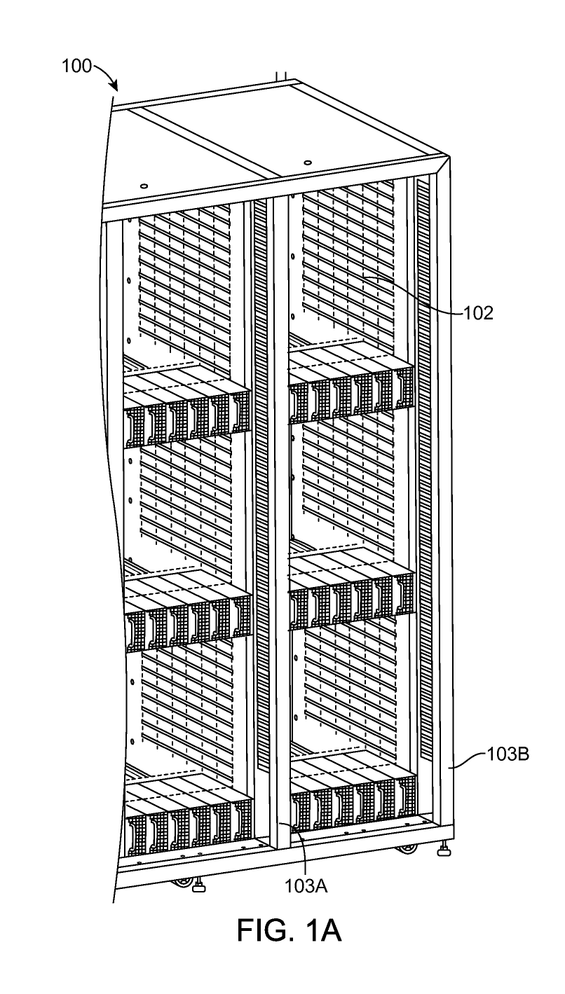

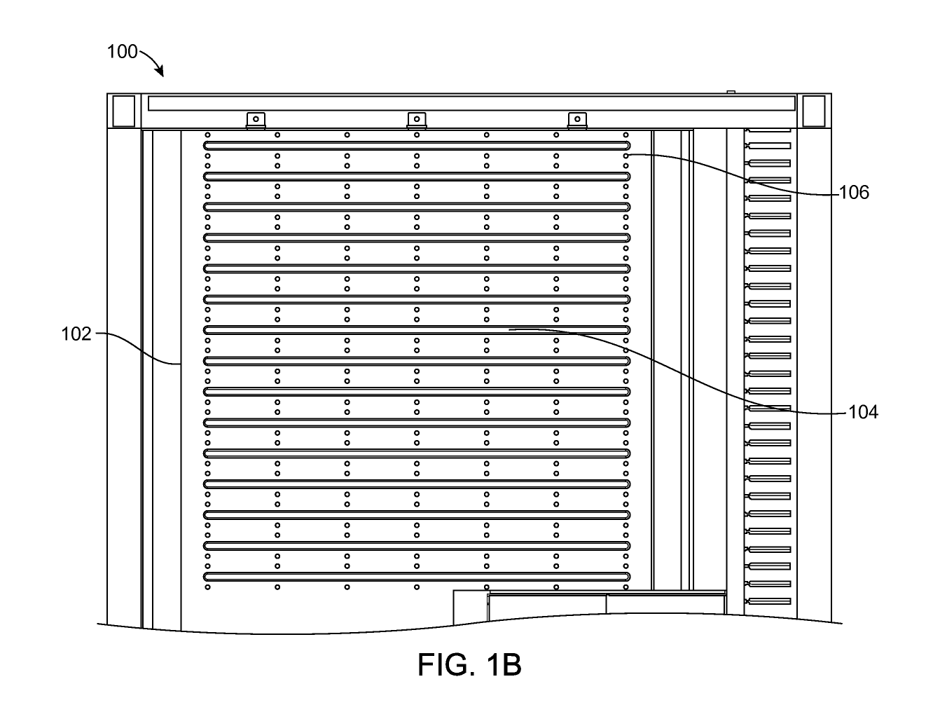

A pair of configurable rack mount side panels (hereinafter referred to as “side panels”) increases the amount of horizontal space available for rack-mounted equipment within a server rack and allows equipment to be mounted within a server rack at smaller height intervals. FIG. 1A illustrates an example of a side panel 102 installed in a server rack 100. In the illustrated embodiment, a front of the server rack 100 includes two posts 103A, 103B. A front side of the illustrated side panel 102 is secured to the second post 103B, and the front side of an additional side panel (not shown in FIG. 1A) is secured to the first post 103A opposite the illustrated side panel 102. Hence, the side panel 102 and the additional side panel are parallel to each other. In some embodiments, the rear of the server rack 100 includes two additional posts, and the side panels 102 are also secured to the rear posts for added stability.

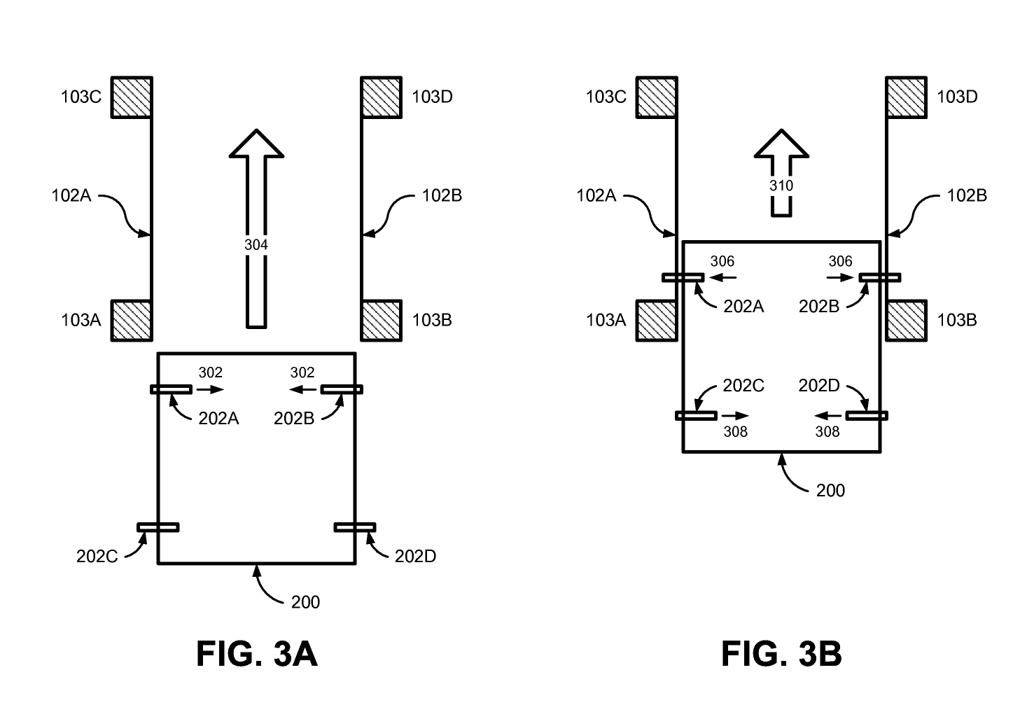

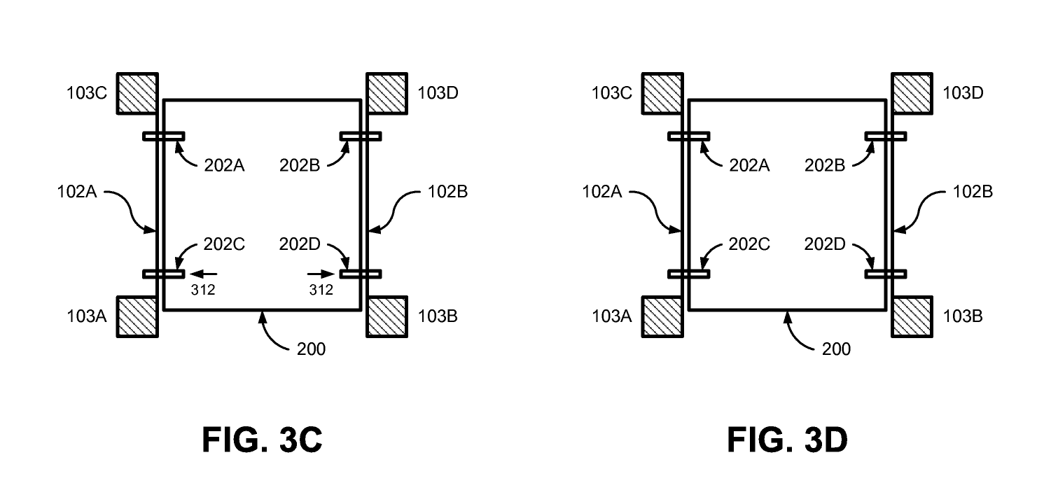

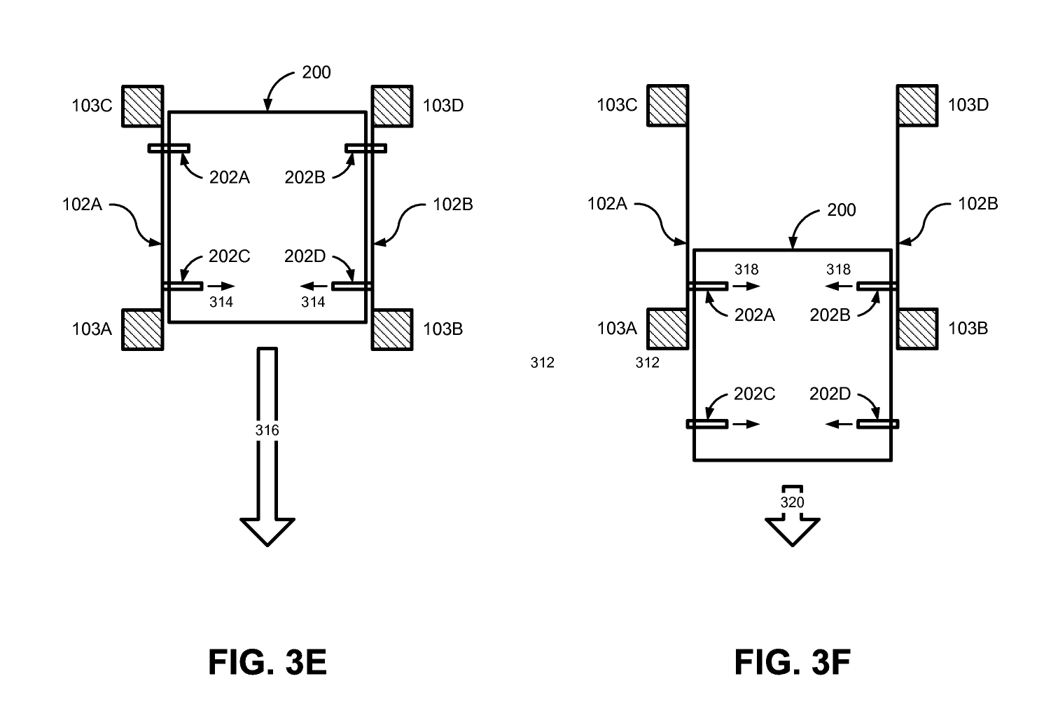

FIG. 1B is a side view of the side panel 102 shown in FIG. 1A. The side panel 102 includes a plurality of slots 104 for mounting computing assets (e.g., servers) to the side panel 102. The slots are perpendicular to an opening of the rack 100. For example, the rack 100 includes a vertical opening, as shown in FIG. 1, and the slots 104 are horizontally oriented. Mounting computing assets to the side panel 102 using the slots 104 is described below with reference to FIGS. 3A-3D. The side panel 102 may also include a plurality of holes 106 that may be used in addition to, or in place of, the slots 104 to secure computing assets to the side panel 102. The holes 106 may also be used to secure other hardware to the side panel 102, such as mounting brackets or sliding rails (i.e., for computing assets that will be slid out more frequently). In some embodiments, the holes 106 are threaded to engage screws or other threaded fasteners.

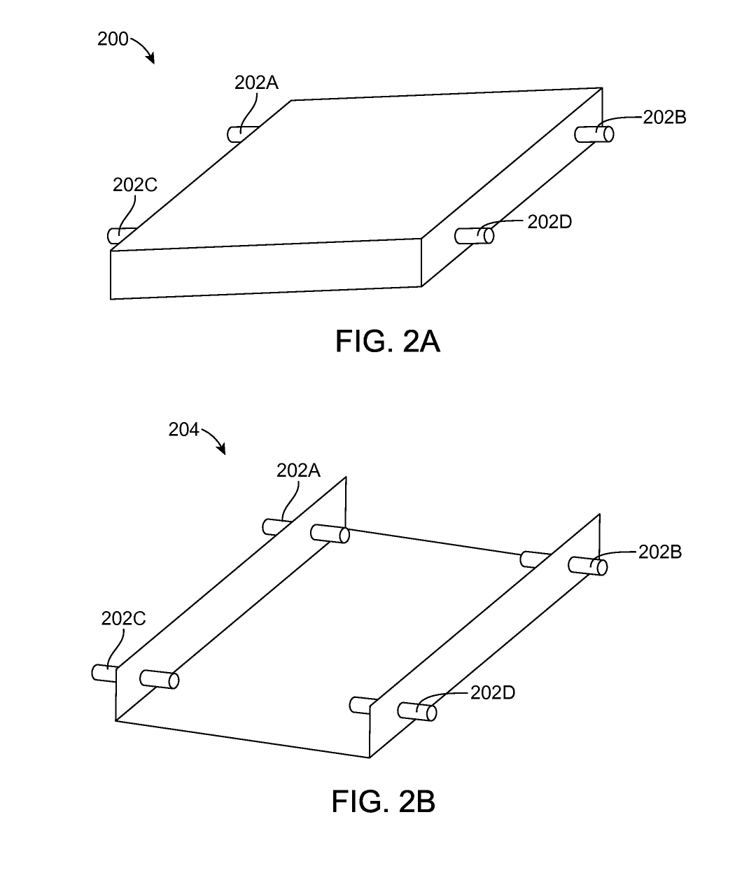

FIG. 2A illustrates a chassis 200A that for mounting on the side panels 102. As used herein, a chassis is any rigid frame that supports circuit boards or other electronic devices. Each side of the chassis 200A includes a plurality of protruding pins that engage with the slots 104 in the opposing side panels 102 to support the chassis 200A. In the illustrated embodiment, two pins 202A, 202C are included on a side of the chassis 100 and two pins 202B, 202D are on an additional side of the chassis 200A that is parallel to the side including pins 202A, 202C. In other embodiments, additional pins may be placed on each side of the chassis 200A so that less weight is placed on each pin.

The chassis 200A of FIG. 2A forms an enclosure suitable for housing any type of computing asset. In one embodiment, the computing asset housed in the chassis 200A is a server that is dedicated to running services for a plurality of computing devices connected over a network. Alternatively, the computing asset may be a personal computer, a network-attached storage system (NAS), networking equipment (e.g., a router, hub, or switch), or some other electronic device.

In addition to the embodiment shown in FIG. 2A, other types of chasses may also be mounted on the side panels 102. FIG. 2B illustrates a tray-shaped chassis 200B that may be used to support a smaller chassis or housing. Similar to the chassis 200A shown in FIG. 2A, the tray-shaped chassis 200B includes a plurality of protruding pins 202A, 202B, 202C, 202D extending from sides of the tray-shaped chassis 200B that are parallel to each other and that engage with the slots 104 in side panels 102 that are parallel to each other. As further described below, a chassis 200 may have the enclosure shape shown in FIG. 2A, the tray shape shown in FIG. 2B, or any other shape including pins 202A, 202B, 202C, 202D protruding from parallel sides of the chassis 200.

The protruding pins 202A, 202B, 202C, 202D may move between two positions relative to the side of the chassis 200. In a first position, a pin 202 is substantially inside the chassis 200 with a small portion of the pin 202 extending outward. In a second position, a significant portion of the pin extends outward from the side of the chassis 200. In one embodiment, each protruding pin 202 is a spring-loaded pin including a spring that pushes the pin outward into the second position. In this embodiment, the protruding pin 202 may also have a latching mechanism that holds the pin 202 in the first position by keeping the spring compressed. During the mounting process, which is described below with reference to FIGS. 3A and 3D, the pins 202 are withdrawn into the first position, lined up with the slots 104 in the opposing side panels 102, and extended into the second position to engage the slots 104.

FIG. 3A is a top-down view of a chassis 200 prior to being mounted on a pair of opposing side panels 102A, 102B in a server rack 100. In the embodiment illustrated in FIG. 3A, the rack 100 includes four posts 103A, 103B, 103C, 103D. A side panel 102A is secured to posts 103A, 103C, and the additional side panel 102B is secured to posts 103B, 103D. In one embodiment, the server rack 100 conforms to the EIA-310-D standard, so the width between posts 103 is approximately 17.6 inches. As the side panels 102A, 102B are secured to the posts 103, the width between the side panels 102A, 102B is also approximately 17.6 inches in this embodiment.

At the beginning of the mounting process, a user moves 302 the two pins 202A, 202B at the rear of the chassis 200 into the first position. The pins 202A, 202B may be pushed into the first position from outside the chassis 200 or pulled from inside the chassis 200. Next, the user moves 304 the chassis 200 into the space between the opposing side panels 102A, 102B and aligns the pins 202A, 202B with forward ends of two slots 104 on the side panels 102A, 102B. FIG. 3B illustrates the chassis 200 after the pins 202A, 202B have been aligned with the slots 104. After the alignment is complete, the user moves 306 the pins 202A, 202B to the second position, causing the pins 202A, 202B extend into and engage the slots 104.

Next, the user moves 308 the two pins 202C, 202D at the front of the chassis 200 into the first position and inserts 310 the chassis 200 into the server rack 100. As the two rear pins 202A, 202B are engaged with the slots 104, the slots 104 acts as guides that support the rear of the chassis 200 as the chassis is inserted 310 into the rack 100. After the chassis 200 has been inserted 310 into the rack, as shown in FIG. 3C, the user aligns the pins 202C, 202D with the slots 104 and moves 312 the two front pins 202C, 202D into the second position to engage the slots 104. In some embodiments, the sides of the chassis 200 also include holes that align with the holes 106 on the side panels 102A, 102B, and the user may insert fasteners through these holes to provide additional mounting security. This may be useful in embodiments where the distance between the pins on each side of the chassis 200 (e.g., the pins 202A, 202C or the pins 202B, 202D) is shorter than the length of the slots 104, which would allow the chassis 200 to move forward and backward if mounted using only the protruding pins 202A, 202B, 202C, 202D. In other embodiments, chassis 200 includes two pins (e.g., the pins 202C, 202D are omitted), and a fastener is inserted through holes 106 in the side panels 102A, 102B that align with holes in the chassis 200 to prevent the chassis 200 from moving.

FIG. 3D is a top-down view of the chassis 200 after being mounted to the side panels 102A, 102B. The pins 202A, 202C are engaged with a slot 104 on the panel 102A, and pins 202B, 202D, on a side of the chassis parallel to the side including the pins 202C, 202C, are engaged with a slot 104 at a corresponding height on the additional side panel 102B. Together, the protruding pins 202A, 202B, 202C, 202D support the chassis 200 on the side panels 102A, 102B and secure the chassis 200 inside the server rack 100. In contrast to a conventional mounting bracket or sliding rail system, the protruding pins 202A, 202B, 202C, 202D do not occupy horizontal space within the rack 100. As a result, the chassis 200 may span the entire width between the posts 103A, 103B and the posts 103C, 103D. Hence, the mounting system described above allows a wider chassis 200 to be included in a server rack 100 than if a conventional mounting system is used. For example, in an embodiment where the distance between the side panels 102A, 102B is 17.6 inches, the mounting system described herein may accommodate a chassis 200 with a width of 17.6 inches.

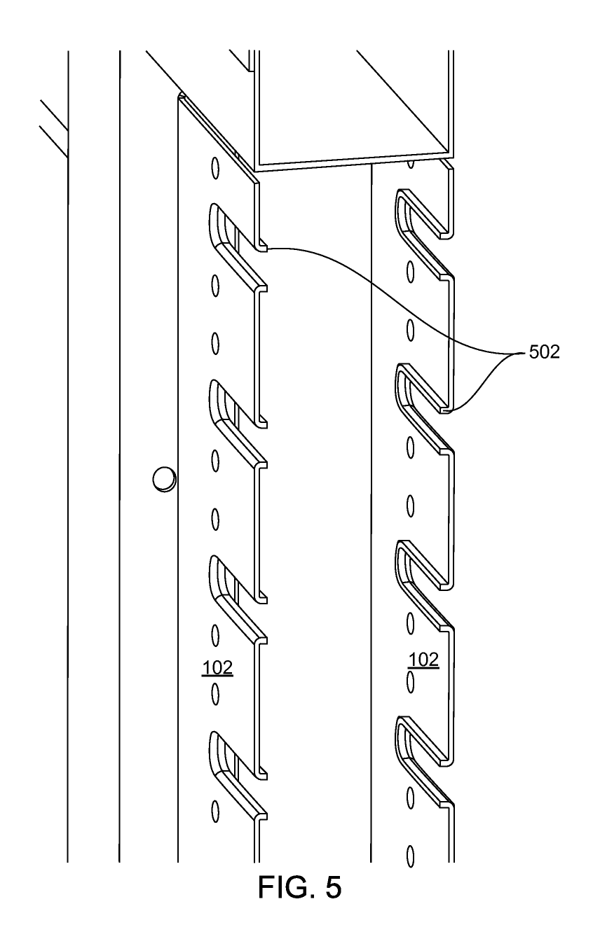

FIGS. 3E and 3F illustrate a process for removing the chassis 200 from the server rack 100. First, the user disengages the two pins 202C, 202D at the front of the chassis 200 by moving 314 the pins 202C, 202D into the first position. In one embodiment, outer surfaces of the side panels 102A, 102B cannot be accessed, so the user reaches into the chassis 200 and pulls the pins 202C, 202D into the first position. For example, because another side panel is installed on the opposite side of the post 103, as shown in FIG. 5.

After the pins 202C, 202D are disengaged, the user pulls 316 the chassis 200 forward, or towards an opening of the server rack 100. As the two pins 202A, 202B in the rear of the chassis 200 remain engaged with the slots 104, the chassis 200 slides forward on the slots 104 as the user pulls 316. After the pins 202A, 202B reach the ends of the slots 104, the user moves 318 the rear pins 202A, 202B into the first position. This disengages the chassis 200 from the slots 104, and the chassis 200 can be removed 320 from the rack 100.

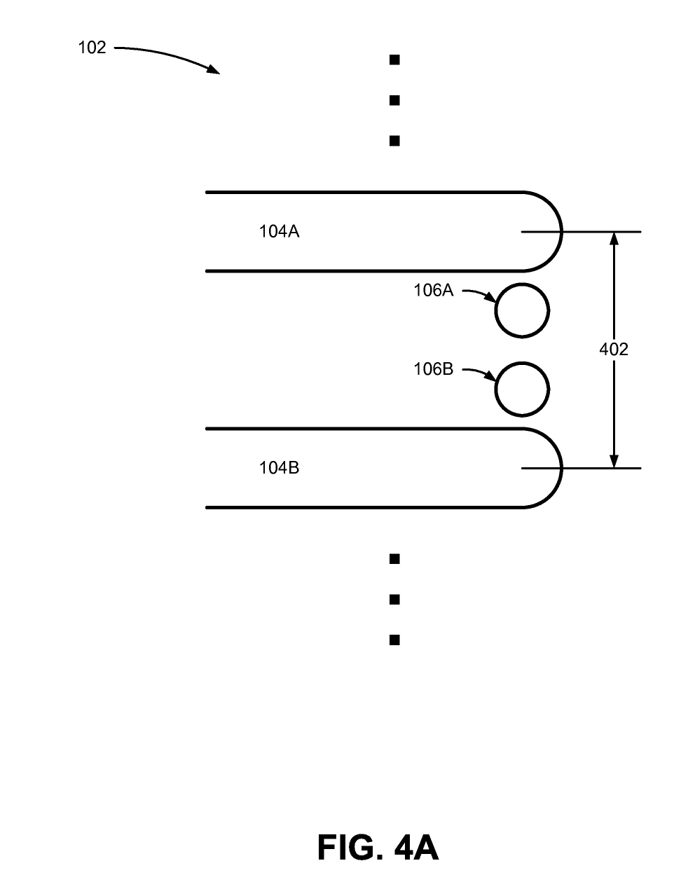

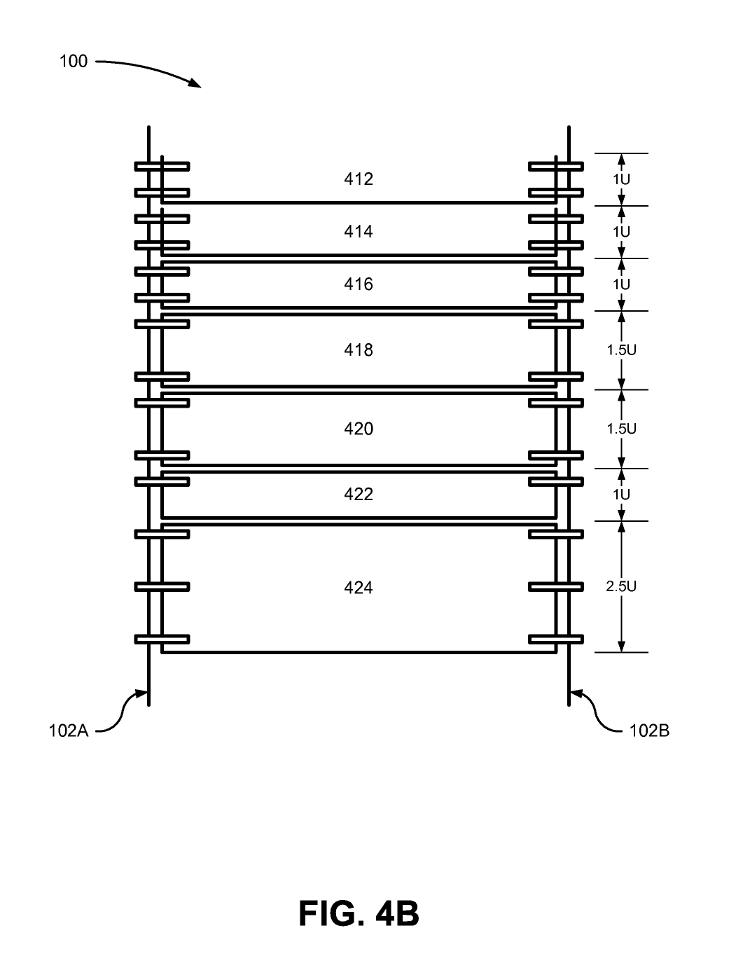

FIG. 4A is a closer side view of a side panel 102. As described above with reference to FIG. 1B, the side panel 102 includes a plurality of horizontal slots 104 and may optionally include a plurality of holes 106. In one embodiment, the distance 402 between two adjacent slots 104A, 1064B is 0.875 inches, which is half of one rack unit (e.g., 0.5 U). FIG. 4B shows chasses 412, 414, 416, 418, 420, 422, 424 of varying heights mounted on a server rack 100 with side panels 102A, 102B. Several of the chasses (i.e., 418, 420, and 424) have non-integer rack unit heights (i.e., 1.5 U, 2.5 U). Because conventional server racks only allow equipment to be mounted at intervals of 1 U, there would be 0.875 inches (0.5 U) of wasted space above each of these chasses 418, 420, 424 if mounted in a conventional server rack. However, the 0.5 U spacing of the slots 104 allows other chasses to be mounted immediately above and below these chasses, reducing the amount of unused space if chasses with non-integer rack unit heights (e.g., 0.5 U, 1.5 U, 2.5 U) are mounted in the server rack 100.

In some embodiments, the slots 104 may have embossed edges 502, as shown in the cross-sectional view of FIG. 5. Embossed edges 502 increase the surface area of the slots 104 contacting the protruding pins 202, which reduces the pressure exerted on the edges of the slots 104 by the pins 202. This increases the load bearing capacity of the slots 104, allowing heavier equipment to be mounted on the side panels 104 using fewer pins 202.

### SUMMARY

The foregoing description of the embodiments of the invention has been presented for the purpose of illustration; it is not intended to be exhaustive or to limit the invention to the precise forms disclosed. Persons skilled in the relevant art can appreciate that many modifications and variations are possible in light of the above disclosure.

Finally, the language used in the specification has been principally selected for readability and instructional purposes, and it may not have been selected to delineate or circumscribe the inventive subject matter. It is therefore intended that the scope of the invention be limited not by this detailed description, but rather by any claims that issue on an application based hereon. Accordingly, the disclosure of the embodiments of the invention is intended to be illustrative, but not limiting, of the scope of the invention, which is set forth in the following claims.

What is claimed is:

1. A system comprising:
a chassis for housing a computing asset;
at least one spring loaded pin on each of a pair of opposing sides of the chassis, the spring loaded pins each comprising a protruding element and a spring configured to push the protruding element outside of the chassis; and
a rack for holding a plurality of rack-mounted computing assets, the rack comprising a pair of opposing side panels for supporting the rack-mounted computing assets, the side panels comprising a plurality of slots for receiving the protruding elements of the spring loaded pins to support the chassis in the rack.

2. The system of claim 1, wherein the side panels further include a plurality of holes for coupling to the chassis to the rack.

3. The system of claim 2, wherein the plurality of holes are threaded.

4. The system of claim 1, wherein the panels are separated by a distance of at least 17.6 inches.

5. The system of claim 1, wherein a rack-mounted computing asset is a server.

6. The system of claim 1, wherein the plurality of slots are parallel to each other.

7. The system of claim 1, wherein slots in the plurality of slots are separated by a distance of 0.875 inches.

8. The system of claim 1, wherein the plurality of slots are perpendicular to an opening of the rack.

9. The system of claim 1, wherein one or more of the plurality of slots have embossed edges.

10. The system of claim 1, wherein the rack comprises at least two posts, and wherein the side panels are collinear to the posts.

11. A system comprising:
a chassis for housing an electronic device, each of a pair of opposing sides of the chassis having at least one protruding pin; and
a rack comprising a pair of opposing side panels for supporting the chassis, each of the opposing side panels including a slot perpendicular to an opening of the rack for receiving the protruding pin of the chassis;
wherein the chassis is configured to be coupled to the opposing side panels by engaging the protruding pins near an end of the slots and moving the chassis in a direction parallel to the slots so that the protruding pins are moved toward a distal end of the slots.

12. The system of claim 11, wherein the side panels further comprise a plurality of threaded holes for coupling the chassis to the rack.

13. The system of claim 11, wherein the side panels are separated by a distance greater than 17.6 inches.

14. The system of claim 11, wherein a side panel includes a plurality of slots having a distance of 0.875 inches between the slots.

15. The system of claim 11, wherein the slots have embossed edges.

16. The system of claim 11, wherein the rack comprises at least two posts, and wherein the opposing side panels are collinear to the posts.

17. A method comprising:
engaging a first protruding pin near a first end of a first slot on a first side panel of a rack, the first protruding pin mounted to a first side of a chassis;
engaging a second protruding pin near a first end of a second slot on a second side panel of the rack, the second protruding pin mounted to a second side of the chassis; and
moving the chassis in a direction parallel to the slots so the first protruding pin and the second protruding pin are moved toward a second end of the first slot distal to the first end of the first slot and toward a second end of the second slot that is distal to the first end of the second slot.

18. The method of claim 17, wherein the first protruding pin and the second protruding pin are spring-loaded.

19. The method of claim 17, wherein the first slot and the second slot each have embossed edges.

20. The method of claim 17, wherein the rack comprises at least two posts, and wherein the first side panel and the second side panel are collinear to the posts.

21. The method of claim 17, further comprising:
moving the first protruding pin into the chassis to disengage the first protruding pin from the first horizontal slot;
moving the second protruding pin into the chassis to disengage the second protruding pin from the second horizontal slot;
moving the chassis in a direction parallel to the slots so the first protruding pin and the second protruding pin are moved toward the first end of the first slot and toward the first end of the second slot; and
removing the chassis from the rack.
